(19) United States
(12) Patent Application Publication
(10) Pub. No.: US 2024/0431215 A1
(43) Pub. Date: Dec. 26, 2024

(54) FABRICATION OF A SCALABLE QUANTUM SENSING DEVICE THROUGH PRECISELY PROGRAMMABLE PATTERNING SPIN DEFECTS ON UNIVERSAL SUBSTRATES

(71) Applicant: Versitech Limited, Hong Kong (CN)

(72) Inventors: Jitae Kim, Hong Kong (CN); Zhaoyi Xu, Hong Kong (CN); Zhiqin Chu, Hong Kong (CN); Lingzhi Wang, Hong Kong (CN)

(73) Assignee: Versitech Limited, Hong Kong (CN)

(21) Appl. No.: 18/686,153

(22) PCT Filed: Aug. 19, 2022
(86) PCT No.: PCT/CN2022/113516

§ 371 Date: Feb. 23, 2024

Related U.S. Application Data
(60) Provisional application No. 63/236,411, filed on Aug. 24, 2021.

(51) Int. Cl. H10N 50/01; B41J 2/04; B82Y 30/00; H10B 69/00; H10N 50/20

(52) U.S. Cl. CPC H10N 50/01; B82Y 30/00; H10N 50/20; B41J 2/04; B41J 2002/043; H10B 69/00

(57) ABSTRACT

A method of fabricating a nitrogen-vacancy (NV) center quantum sensing device based on electrohydrodynamic (EHD) printing. A nanopipette with an aperture at one end is filled with nanodiamond suspension ink so the ink is present in a meniscus at The aperture, the nanodiamond suspension ink comprises nanodiamonds and solvent. The nanopipette is supported above a substrate having a back electrode. A DC is applied pulse between the nanopipette and the back electrode so as to generate an electrostatic attractive force resulting in the ejection of nano-diamond-laden droplets with sub-attoliter volume. The droplet lands on the substrate and is allowed to dry due to solvent evaporation. Using the method, the control of the number of printed nano-diamonds is at will, attaining single-particle level precision. This printing approach, therefore, enables printing NV center arrays with a controlled number directly on the substrate without any lithographic process.

This application is a U.S. National Stage Application under 35 U.S.C. § 371 of International Patent Application No. PCT/CN2022/113516, filed Aug. 19, 2022, and claims the benefit of priority under 35 U.S.C. Section 119 (e) to U.S. Provisional Application No. 63/236,411, filed on Aug. 24, 2021, the disclosures of which are incorporated herein by reference in their entireties as a part of this application. The International Application was published in English on Mar. 2, 2023 as International Publication No. WO 2023/025049 under PCT Article 21 (2).

### FIELD OF THE INVENTION

The present invention relates to solid-state elements for quantum information processing and, more particularly, to nitrogen-vacancy center quantum sensing devices.

### BACKGROUND OF THE INVENTION

Nitrogen-vacancy (NV) centers or spin defects in nanodiamonds have emerged as a promising solid-state element for quantum information processing [1-8], quantum optics [9-11], and nanoscale quantum sensing [12-14]. In particular, NV centers show their quantum characteristics and robustness at room temperature [5, 6, 15, 16], offering an important step for the practical realization of quantum devices. Exploiting their full capabilities necessitates a strategy to manipulate and access them individually on photonic circuits.

Considerable research has been conducted on the production and placement of NV centers. The generation of NV centers in diamond has mainly relied on ion implantation. The use of focused nitrogen [17], helium ion [18], or electron beam irradiation have also produced high-precision NV centers with sub-micrometer spatial resolution, which has been a great breakthrough in fundamental research. However, the incompatibility of diamond with conventional microfabrication processes limits the practical realization of nanophotonic devices.

Alternative methods that use nano-sized diamond particles have been devised to improve the compatibility with various substrates and circuits [20-22]. First, stochastic methods based on drop-casting or spin-coating provide a simple and cost-effective route to place NV-center nano-diamonds on substrates [20], but suffer from randomness in the particle positioning. “Pick-and-place” methods that use a nano-manipulator with real-time observation have been implemented to improve the positional accuracy [21, 23] and have demonstrated exciting progress regarding the near-field coupling of NV centers to nanophotonic structures. These sophisticated methods, however, challenge the ability to satisfy the required throughput. Although lithographically prepared electrostatic patterns [22, 24, 25] have recently been utilized for large-scale integration of NV centers, a universal and flexible manufacturing route is still in great demand for achieving nanoscale accuracy, scalability, cost-effectiveness and efficient coupling with a wide range of nanophotonic circuitries.

### SUMMARY OF THE INVENTION

In order to overcome the drawbacks of the prior art, the present invention uses an electrohydrodynamic (EHD) dispensing method to print nanodiamonds with nitrogen vacancy (NV) centers having programmed quantity and position, directly on a substrate without the need for any lithography process. The EHD ejection dynamics and suspension stability of nano-diamond-laden droplets with sub-attoliter volume (<10⁻¹⁸ L) are shown to achieve a high-precision, high-fidelity printing process. The results demonstrate sub-wavelength positional accuracy, quantum-level, on-demand quantity control and freeform patterning capability. This direct printing approach offers a simple, flexible and cost-effective route to placing diamond defects serving as promising quantum elements.

The present invention is a process for forming nanodiamonds with NV centers by using EHD printing of droplets containing nanodiamonds when a DC voltage is applied to a back electrode of a substrate. A nanopipette is used to eject a nanodiamond-laden nanodroplet on a substrate having a charged electrode on its back so that the droplet gently lands on the substrate. The nanodroplet is allowed to dry due to wetting-enhanced solvent evaporation. A nanodiamond cluster is formed after the solvent evaporation is completed. The nanodiamonds have embedded NV centers that are optically accessible. By means of relative movement between the nanopipette and the substrate, an array of nanodiamond clusters with NV centers is formed.

### BRIEF SUMMARY OF THE DRAWINGS

The foregoing and other objects and advantages of the present invention will become more apparent when considered in connection with the following detailed description and appended drawings in which like designations denote like elements in the various views, and wherein:

FIGS. 1A-1F illustrate a process for printing nanodiamonds wherein FIG. 1A is a conceptual drawing illustrating electrohydrodynamic (EHD) printing of NV center nanodiamonds when a DC voltage is applied to a back electrode, FIG. 1B shows a nanodiamond-laden nanodroplet ejected on a charged electrode back, FIG. 1C shows the nanodroplet gently landing on the substrate and dried due to wetting-enhanced solvent evaporation, FIG. 1D shows a nanodiamond cluster formed after solvent evaporation is completed and the embedded NV centers are optically accessible, FIG. 1E is an FE-SEM image of an array of NV center nanodiamond clusters, FIG. 1F is a confocal florescence image of an array of NV center nanodiamond clusters under 532 nm excitation, and FIGS. 1G and 1H show the effect of voltage wherein FIG. 1G is a graph of the dependence of printing yield on voltage amplitude and FIG. 1H shows the dependence of the printed spot radius on voltage amplitude (the insert being an FE-SEM image of a printed nanodiamond cluster spot achieved with a voltage pulse;

FIGS. 2A-2G illustrate printing yield wherein FIG. 2A is a graph showing printing yield of carboxylated 40-nm nanodiamonds as a function of the ion strength of the suspension; FIGS. 2B-2G showing particle size distributions of the nanodiamond suspension at different ion strengths from 8.6 in FIG. 2B, 12.7 in FIG. 2C, 32.7 in FIG. 2D, 49.4 in FIG. 2E, 131.5 in FIG. 2F to 340.8 μM in FIG. 2G, and FIGS. 2H-2J show an ink concentration effect with FIG. 2H showing FE-SEM images of printed nanodiamond clusters on a spot by varying 40-nm nanodiamond ink concentrations from a) 4, b) 2 to c) 1 μg/mL, FIG. 2I shows number distribution histograms of printed nanodiamonds per spot at different ink concentrations from 4 (dark blue), 2 (violet), to 1 μg/mL (pink), and FIG. 2J is a graph of statistical means of numbers of printed nanodiamonds per spot at different ink concentrations;

FIGS. 3A-3D are FE-SEM images of printed nanodiamond clusters on a spot with varying electric pulse lengths from 20 in FIG. 3A, 15 in FIG. 3B, 10 in FIG. 3C, to 5 ms in FIG. 3D, under a constant voltage, FIG. 3E shows number distribution histograms of printed nanodiamonds per spot at different pulse lengths from 20 (red), 15 (green), 10 (blue), to 5 ms (yellow), FIG. 3F is a plot of statistical means of numbers of printed nanodiamonds per spot at different electric pulse lengths, FIG. 3G is a plot of the radius of printed nanodiamond spot, r versus pulse length, t;

FIGS. 4A-4C illustrate the number of nitrogen vacancy centers on a printed spot, wherein FIG. 4A is a confocal fluorescence image of a 5×5 printed nanodiamond array, FIG. 4B shows a measured second-order correlation functions g⁽²⁾(τ) of corresponding fluorescence spots, FIG. 4C shows the number distribution histogram of NV centers per spot, FIG. 4D is a plot of the ODMR signal of printed NV center nanodiamond without an external magnetic field; and

FIGS. 5A-5B show on-demand printing of NV centers where FIG. 5A is an FE-SEM image of an NV center pattern shaped with “HKU” and FIG. 5B shows a corresponding wide-field fluorescence image.

### DETAILED DESCRIPTION

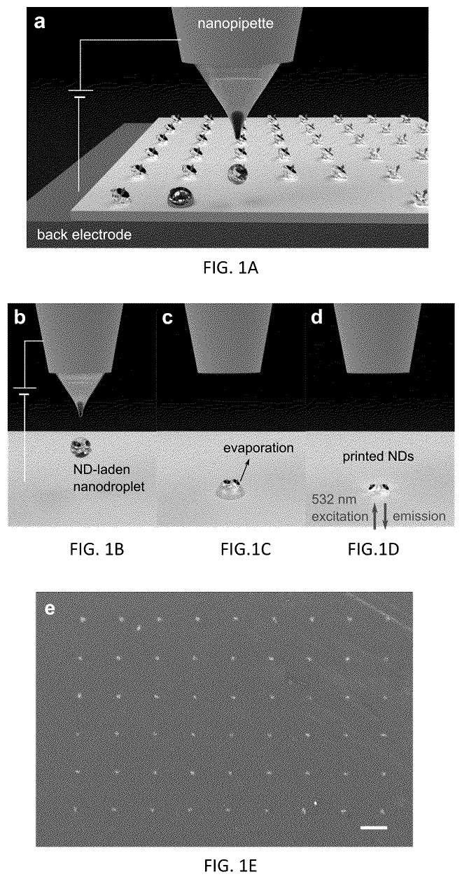

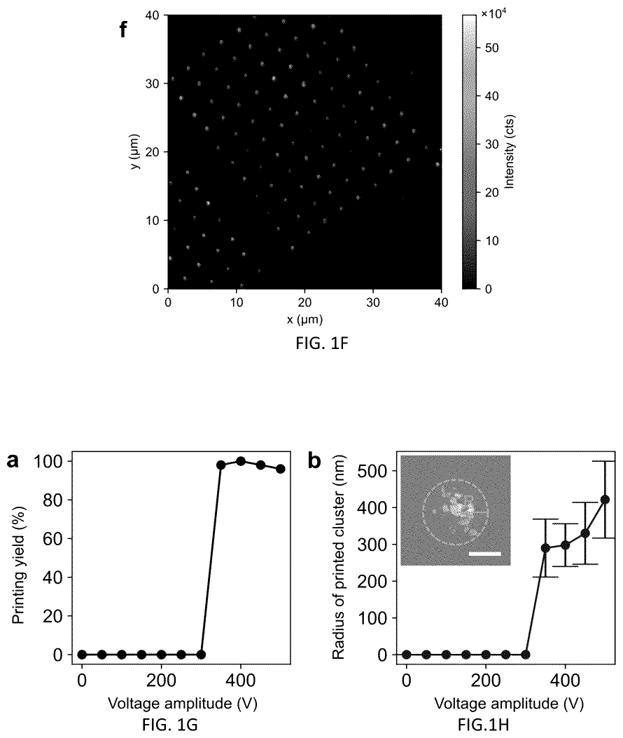

FIG. 1A depicts the concept of nanodiamond printing based on EHD dispensing. A glass nanopipette having an aperture diameter of 800 nm is filled with 40-nm nanodiamond suspension ink (carboxylated, 1˜4 NV centers per particle, 74% fluorescent particle) and is placed at a fixed separation of 5 μm from a substrate. The concentration of the nanodiamond solution ranges from 1 to 4 μg/mL suspended in deionized water. The substrate, which may be a silicon wafer, cover glass, etc., is placed on a back electrode mounted on a three-axis stepping motorized stage having 250 nm movement precision.

When a DC pulse with programmed voltage amplitude and length is applied to the back electrode, an electrostatic attractive force is generated between the ink meniscus at the nanopipette and the substrate, resulting in the ejection of a nano-diamond-laden nanodroplet with sub-attoliter volume, i.e. <10⁻¹⁸ L (FIG. 1B). The electrical pulse may be ˜350 to ˜370 volts with a length of 5˜20 ms. Once the droplet lands on the substrate, solvent rapidly evaporates (FIG. 1C), forming a nanodiamond cluster with a minute particle number. The electron spins of NV centers embedded in the printed cluster are then optically addressable under 532 nm laser excitation (FIG. 1D). Note that “printing yield” is defined as the number of printed nanodiamond clusters by one hundred attempts, which is used for quantitative studies of the invention.

FIG. 1E is a field-emission scanning electron microscope (FE-SEM) image of a 9×6 array of nanodiamond clusters with a pitch of 3 μm printed on a silicon wafer substrate by applying to the back electrode a 360 V pulse with a pulse width of 20 ms for each spot. FIG. 1F shows a confocal photoluminescence (PL) image of the printed cluster array exhibiting 100% fluorescence spots. Quantitatively, a voltage amplitude higher than 350 V results in over 98% printing yield, as the electrostatic force overcomes the surface tension of the ink meniscus (FIG. 1G). FIG. 1H shows an increasing trend of the printed cluster radius (marked as R in the inset FE-SEM image) with the voltage amplitude due to enhanced EHD ink flow. The EHD printed nanodiamond clusters exhibit well-defined NV-center fluorescence under 532 nm laser excitation.

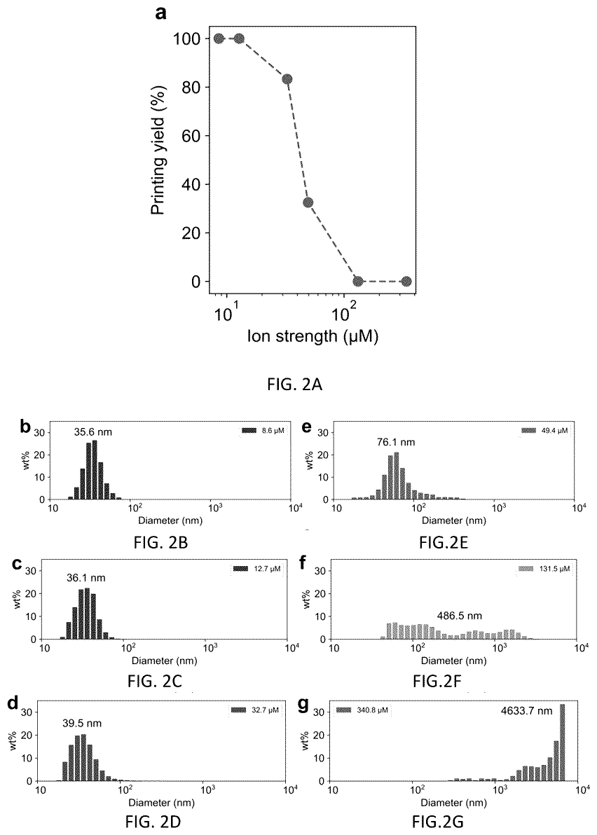

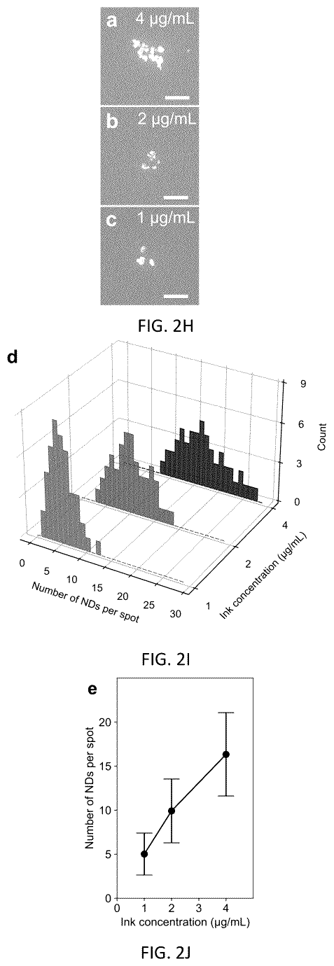

The printing yield, i.e., the consistency of the nanodiamond printing, relies on the dispersion stability of the nanodiamond ink. Uniformly dispersed ink helps to obtain a high production yield of nanodiamond-laden droplets. On the other hand, nanodiamond aggregates may cause clogging of the nanopipette. To achieve a satisfactory printing yield, carboxylated nanodiamonds, stabilized by electrostatic (double-layer) repulsive forces originating from negative surface charges, are used. Besides, it is necessary to control the physical, chemical environment that can influence the dispersion stability. For example, FIG. 2A shows the effect of ion strength on the printing yield. At ionic strengths below 13 μM, ˜100% printing yields are obtained. The particle size distributions at 8.6 μM (FIG. 2B) and 12.7 μM (FIG. 2C) show the average values of 35.6 nm and 36.1 nm, respectively, similar to the single-particle diameter of ˜40 nm. As the ion strength increases from 32.7 μM, 49.4 μM, 131.5 μM, to 340.8 μM, the printing yield drastically decreases from 83.3%, 32.5%, 0%, to 0%, respectively (FIG. 2A), due to the acceleration of the particle aggregation shown in FIGS. 2D-2G. The screen of the electrostatic repulsive forces among nanodiamonds is displayed by a zeta potential decrease from −8.1 mV to −0.1 mV. The result indicates that stable dispersion of the ink is a key requirement for reliable printing.

The number of printed nanodiamonds can be controlled at will by varying printing parameters such as ink concentration and applied pulse length. FIG. 2H presents the dependence of the nanodiamond number on ink concentration, printed by a constant electric pulse with a voltage of 360 V and a length of 20 ms. It is clear from the FE-SEM images of printed nanodiamond clusters (FIG. 2H, images a-c) and the number distribution histograms at different ink concentrations from 4 μg/mL, 2 μg/mL, to 1 μg/mL (FIG. 2I) that ink dilution decreases the nanodiamond number per printed spot. The statistical mean particle numbers are 16.34±4.73, 9.92±3.62, and 5.02±2.39 at 4 μg/mL, 2 μg/mL, and 1 μg/mL, respectively (FIG. 2J).

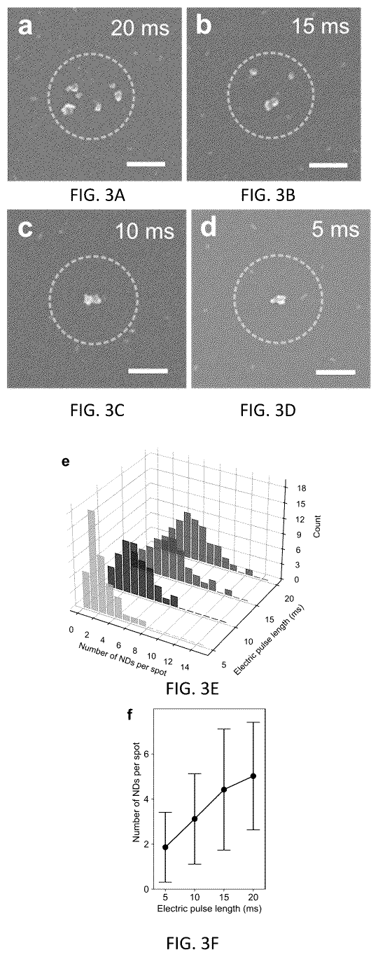

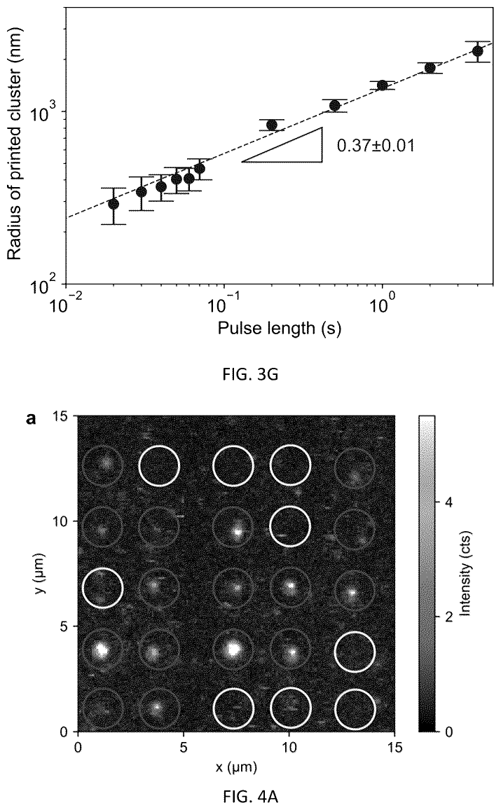

A further decrease in the printed nanodiamond number is achieved by shortening the electric pulse length. The FE-SEM images in FIGS. 3A-3D show a decrease in the nanodiamond number per printed spot as the pulse length shortens from 20 ms, 15 ms, 10 ms, to 5 ms, using 1 μg/mL ink (voltage amplitude: 360 V). FIG. 3E shows that the corresponding number distribution histograms shift to decrease and become narrower as the pulse length shortens. The statistical mean values of the nanodiamond numbers per printed spot are 5.02±2.39, 4.42±2.69, 3.12±1.55, and 1.86±1.55 at 20 ms, 15 ms, 10 ms, and 5 ms, respectively (FIG. 3F). Over 38% of the printed spots are achieved with only a 5 ms pulse containing a single nanodiamond, indicating that the on-demand printing of the present invention enables single-particle level control. This control approach is associated with the dependence of ink ejection volume on electric pulse length. FIG. 3G plots a functional dependence of the printed spot radius, r on pulse length, t, corresponding to r(t)=Kt^{0.37±0.01}, where K is the proportionality constant. The growth exponent of 0.37+0.01 similar to ⅓ implies a constant flow rate at a constant voltage in this experiment. The mean radius of the printed cluster achieved with a 20 ms pulse is measured as 289.8±68.9 nm, demonstrating a subwavelength emission spot size.

To prove the quantum-level on-demand printing, Hanbury-Brown and Twiss (HBT) measurements were performed and the intensity-time traces were analyzed to deduce the second order correlation functions g⁽²⁾(τ) under 532 nm laser excitation. Analyzing g⁽²⁾(0) enables the counting of the number of NV centers in a printed spot, according to g⁽²⁾(0)=1−(1/m), where m

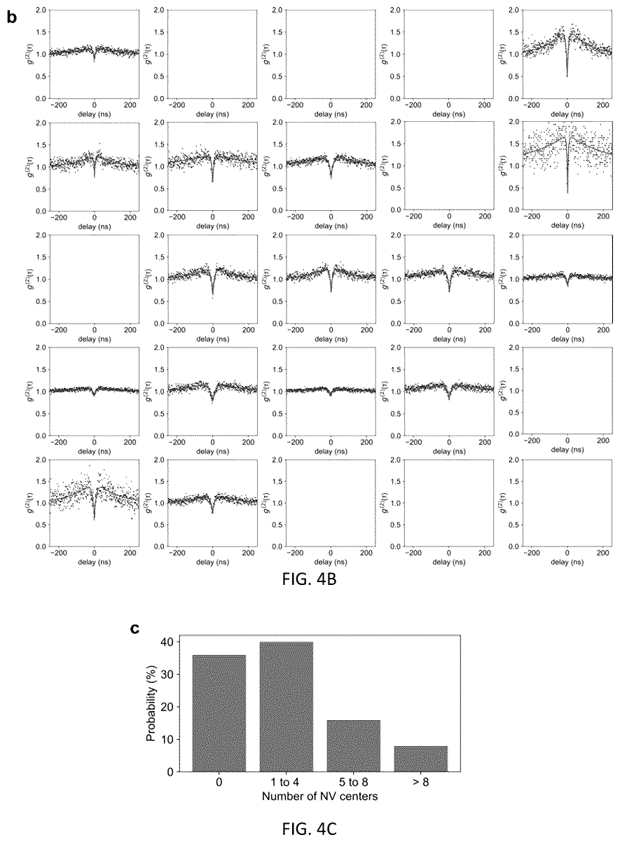

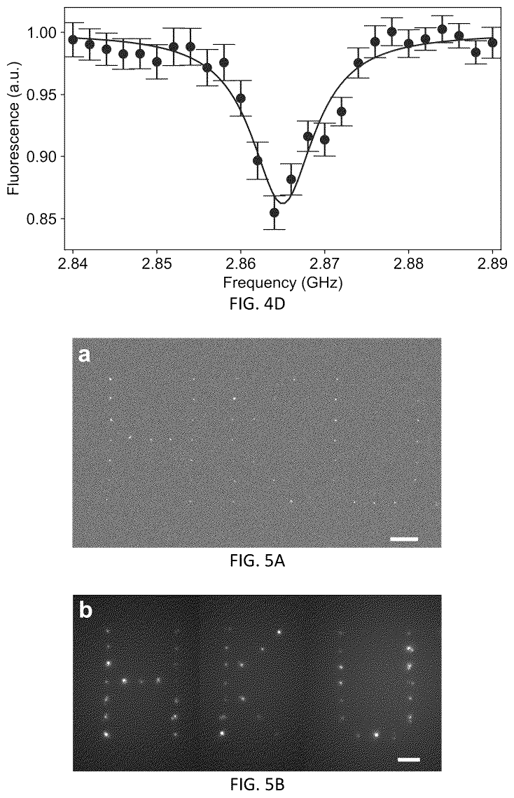

denotes the number of quantum emitters. [26] FIG. 4A displays a confocal fluorescence image of a 5×5 array of nanodiamonds printed on a glass substrate, by applying an electric pulse with a voltage amplitude of 360 V and a length of 5 ms to 1 μg/mL 40-nm nanodiamond ink (1˜4 NV centers per particle, 74% fluorescent particle). The printing condition chosen can deliver 1.86±1.55 nanodiamonds per spot, as discussed in connection with FIG. 3. The fluorescence signals show the existence of NV centers. FIG. 4B plots the corresponding g⁽²⁾(τ). The measured g⁽²⁾(0) gives a statistical result of the number of printed NV centers (FIG. 4C): 40% of the printed spots contain 1˜4 NV centers (4% of the printed spots contain only 1 NV center), 16% contain 5˜8 NV centers, and 8% contain more than 8 NV centers. No fluorescence signal is observed from 36% of the printed spots due to the absence of NV centers at a similar rate to the statistical data of the nanodiamond ink. Also, the optically detected magnetic resonance (ODMR) signal of a printed NV-center nanodiamond can be observed. In the absence of an external magnetic field, the observed resonance frequency of ˜2.87 GHz corresponds to the zero splitting of the NV center (FIG. 4D). The result demonstrates the capability of the present invention to print a small number of NV centers directly on the substrate by a single-step process.

The maskless, open-nanofluidic technique of the present invention enables the on-demand placement of NV-center nanodiamonds in arbitrary patterns. FIGS. 5A and 5B show an exemplary nanodiamond pattern with a “HKU” shape printed on a glass substrate. The FE-SEM image in FIG. 5A shows the printing pattern consisting of nanodiamond cluster spots with a pitch of 3 μm and a positional accuracy <127 nm. The corresponding fluorescence image (FIG. 5B) confirms all the spots in the pattern contain NV centers. Although only a few simple examples are shown, the method can directly print various patterns made up of quantum emitters.

The present invention is a direct nanoscale EHD printing process that allows for placement of NV-center nanodiamonds at will. On-demand control over the quantity and position of printed NV centers has been demonstrated by thoroughly characterizing the printing conditions. As a result, the printed matter has reached the quantum level. The method is simple and general and therefore can be extended for printing various nanodiamonds with different sizes, defect densities and species, e.g., SiV—centers. Furthermore, this lithography-free approach lowers the technological barriers to the integration of solid-state quantum elements into diverse nanophotonic quantum circuits.

### Experiments

Preparation: 40-nm fluorescent NV center nanodiamond suspension (carboxylated, 1˜4 NV centers per particle, 0.1 wt % in deionized water, purchased from Adámas Nanotechnologies), was used. The printing ink was prepared by diluting the nanodiamond suspension in deionized water by a factor of 1000 and adding 0.1 wt % of TX100 (Sigma Aldrich) to adjust the surface tension. For preparing a printing nozzle, a borosilicate glass nanopipette having a diameter of 800 nm was fabricated by a programmed heat-pulling process (P-97 Flaming/Brown Micropipette Puller, Sutter Instrument). The prepared nanopipettes, silicon substrates, and glass substrates were cleaned by rinsing with acetone, isopropyl alcohol, and deionized water under sonication for 5 minutes each and then by O₂ plasma treatment for 5 minutes.

EHD printing: The printer setup consists of a printer head and a platform. The printer head is configured with a glass nanopipette held in a three-axis translation stage and the platform is composed of a three-axis stepping motorized stage with a 50 nm precision (XA05A, ZA05A, Kohzu Precision), an indium tin oxide (ITO)-coated glass plate placed on the stage as a back electrode, and a substrate on the back electrode. During EHD printing, the pipette-substrate gap was fixed to 5 μm and programmed electric pulses with a voltage amplitude of 360 V and a length ranging from 4 s to 5 ms were applied to the back electrode using a pulse generator (NI USB-6212, National Instruments) with an amplifier (AMJ-2B10, Matsusada Precision Inc). The entire EHD printing process was monitored in real-time by using a side-view optical microscope consisting of a long working distance objective (50×, 0.55 NA, Mitutoyo Plan Apo) and a CCD camera (DCC1545M, Thorlabs). The printing was performed under controlled relative humidity by mass flow controllers (SLA5800, brooks instrument) and controlled temperature inside a custom-made environmental enclosure.

Optical characterizations: The characterization of NV-center fluorescence from printed nanodiamonds was carried out using a custom-made confocal laser scanning microscope consisting of an oil immersion objective (NA 1.45 UPLXAPO100XO), a continuous 532 nm laser (300 μW laser power was used during the experiment), λ=647 nm long-pass edge filter (BLP01-647R-25), and two single photon counting modules (SPCM-AQRH-16-FC, Excelitas Technologies). An HBT experiment was performed to characterize the number of NV centers embedded. The emission was divided by a 50/50 fiber optic coupler and collected by two single photon counting modules to obtain the second order correlation function of the time delay. The ODMR measurement (from 2.84-2.90 GHz in steps of 2 MHz) was performed by measuring the fluorescence intensity from the NV-center with an exposure time of 0.1 s.

Material characterizations: The exterior of the printed structures was characterized by an FE-SEM (Sigma 300, Zeiss). Particle size and Zeta potential were measured by Nanotrac Wave (JUSTNANO). The Dynamic Light Scattering module in Nanotrac Wave was used for determining particle size. The Nanotrac Wave FLEX software processed the electrophoretic mobility data by applying the Smoluchowski equation and the result was used for determining Zeta-potential.

### REFERENCES

The cited references in this application are incorporated herein by reference in their entirety and are as follows:
[1] E. Togan, Y. Chu, A. S. Trifonov, L. Jiang, J. Maze, L. Childress, M. G. Dutt, A. S. Sørensen, P. R. Hemmer, A. S. Zibrov, Nature 2010, 466, 730.
[2] M. G. Dutt, L. Childress, L. Jiang, E. Togan, J. Maze, F. Jelezko, A. Zibrov, P. Hemmer, M. Lukin, Science 2007, 316, 1312.
[3] L. Robledo, L. Childress, H. Bernien, B. Hensen, P. F. Alkemade, R. Hanson, Nature 2011, 477, 574.
[4] T. Van der Sar, Z. Wang, M. Blok, H. Bernien, T. Taminiau, D. Toyli, D. Lidar, D. Awschalom, R. Hanson, V. Dobrovitski, Nature 2012, 484, 82.
[5] P. C. Maurer, G. Kucsko, C. Latta, L. Jiang, N. Y. Yao, S. D. Bennett, F. Pastawski, D. Hunger, N. Chisholm, M. Markham, Science 2012, 336, 1283.
[6] F. Dolde, I. Jakobi, B. Naydenov, N. Zhao, S. Pezzagna, C. Trautmann, J. Meijer, P. Neumann, F. Jelezko, J. Wrachtrup, Nature Physics 2013, 9, 139.
[7] H. Bernien, B. Hensen, W. Pfaff, G. Koolstra, M. S. Blok, L. Robledo, T. Taminiau, M. Markham, D. J. Twitchen, L. Childress, Nature 2013, 497, 86.
G. Fuchs, G. Burkard, P. Klimov, D. Awschalom, Nature Physics 2011, 7, 789.
[9] L. P. Neukirch, E. Von Haartman, J. M. Rosenholm, A. N. Vamivakas, Nature Photonics 2015, 9, 653.
G. Balasubramanian, P. Neumann, D. Twitchen, M. Markham, R. Kolesov, N. Mizuochi, J. Isoya, J. Achard, J. Beck, J. Tissler, Nature materials 2009, 8, 383.
H. Bernien, L. Childress, L. Robledo, M. Markham, D. Twitchen, R. Hanson, Physical Review Letters 2012, 108, 043604.
J. Taylor, P. Cappellaro, L. Childress, L. Jiang, D. Budker, P. Hemmer, A. Yacoby, R. Walsworth, M. Lukin, Nature Physics 2008, 4, 810.
[13] H. Mamin, M. Kim, M. Sherwood, C. Rettner, K. Ohno, D. Awschalom, D. Rugar, Science 2013, 339, 557.
[14] G. Kucsko, P. C. Maurer, N. Y. Yao, M. Kubo, H. J. Noh, P. K. Lo, H. Park, M. D. Lukin, Nature 2013, 500, 54.
[15] A. Gruber, A. Dräbenstedt, C. Tietz, L. Fleury, J. Wrachtrup, C. Von Borczyskowski, Science 1997, 276, 2012.
[16] C. Bradac, T. Gaebel, N. Naidoo, M. Sellars, J. Twamley, L. Brown, A. Barnard, T. Plakhotnik, A. Zvyagin, J. Rabeau, Nature nanotechnology 2010, 5, 345.
[17] J. R. Rabeau, P. Reichart, G. Tamanyan, D. N. Jamieson, S. Prawer, F. Jelezko, T. Gaebel, I. Popa, M. Domhan, J. Wrachtrup, Appl. Phys. Lett. 2006, 88, 023113.
[18] F. Fávaro de Oliveira, S. A. Momenzadeh, D. Antonov, J. Scharpf, C. Osterkamp, B. Naydenov, F. Jelezko, A. Denisenko, J. r. Wrachtrup, Nano letters 2016, 16, 2228.
[19] M. Capelli, A. Heffernan, T. Ohshima, H. Abe, J. Jeske, A. Hope, A. Greentree, P. Reineck, B. Gibson, Carbon 2019, 143, 714.
[20] R. Kolesov, B. Grotz, G. Balasubramanian, R. J. Stöhr, A. A. Nicolet, P. R. Hemmer, F. Jelezko, J. Wrachtrup, Nature Physics 2009, 5, 470.
[21] A. Huck, S. Kumar, A. Shakoor, U. L. Andersen, Physical review letters 2011, 106, 096801.
[22] P. Andrich, J. Li, X. Liu, F. J. Heremans, P. F. Nealey, D. D. Awschalom, Nano letters 2018, 18, 4684.
[23] S. Schietinger, M. Barth, T. Aichele, O. Benson, Nano letters 2009, 9, 1694.
[24] M. Kianinia, O. Shimoni, A. Bendavid, A. W. Schell, S. J. Randolph, M. Toth, I. Aharonovich, C. J. Lobo, Nanoscale 2016, 8, 18032.
[25] D. M. Toyli, C. D. Weis, G. D. Fuchs, T. Schenkel, D. D. Awschalom, Nano letters 2010, 10, 3168.
[26] R. Loudon, The quantum theory of light, OUP Oxford, 2000.

While the invention is explained in relation to certain embodiments, it is to be understood that various modifications thereof will become apparent to those skilled in the art upon reading the specification. Therefore, it is to be understood that the invention disclosed herein is intended to cover such modifications as fall within the scope of the appended claims.

1. A method of fabricating a nitrogen-vacancy (NV) center quantum sensing device based on electrohydrodynamic (EHD) printing, comprising the steps of:
providing a nanopipette with an aperture at one end and filled with nanodiamond suspension ink so the ink is present in a meniscus at an end of the aperture, the nanodiamond suspension ink comprising nanodiamonds and solvent;
supporting the nanopipette apart from a substrate having a back electrode;
applying a DC pulse between the nanopipette and the back electrode so as to generate an electrostatic attractive force between the meniscus at the nanopipette and the substrate, resulting in the ejection of nano-diamond-laden droplets with sub-attoliter volume;
allowing the droplet to land on the substrate; and
allowing the droplet to dry due to solvent evaporation.

2. The method of forming nanodiamonds according to claim 1 wherein the nanopipette is made of glass.

3. The method of forming nanodiamonds according to claim 1 wherein the nanodiamonds in the nanodiamond suspension ink are carboxylated.

4. The method of forming nanodiamonds according to claim 1 wherein nanodiamonds in the nanodiamond suspension ink comprises 1˜4 NV centers per particle.

5. The method of forming nanodiamonds according to claim 1 wherein the nanodiamond suspension ink has an ion strength of 13 μM or less.

6. The method of forming nanodiamonds according to claim 1 wherein the nanodiamond suspension ink is prepared by adding TX100.

7. The method of forming nanodiamonds according to claim 1 wherein the nanopipette is supported at a fixed separation from a substrate.

8. The method of forming nanodiamonds according to claim 1 wherein the nanodiamonds in the nanodiamond suspension ink has a concentration of 1-4 μg/mL.

9. The method of forming nanodiamonds according to claim 1 wherein the substrate is supported by a three-axis stepping motorized stage that keeps the nanopipette and substrate at a fixed separation, but allows the substrate to be moved with respect to the nanopipette so that an array of droplets can be printed on the substrate.

10. The method of forming nanodiamonds according to claim 1 wherein the back electrode is an indium tin oxide (ITO)-coated glass plate and the substrate is silicon.

11. The method of forming nanodiamonds according to claim 1 wherein the DC pulse had a voltage amplitude of 350V or more and a length of at least 5 ms.
